(19) United States
(12) Patent Application Publication
(10) Pub. No.: US 2026/0247593 A1
(43) Pub. Date: Aug. 20, 2026

(54) ELECTRONIC COMPONENT MOUNTING SYSTEM AND ELECTRONIC COMPONENT MOUNTING INSPECTION METHOD

(71) Applicant: FUJI CORPORATION, Chiryu (JP)

(72) Inventors: Yuta YOKOI, Kariya-shi (JP); Kazuya KOTANI, Toyota-shi (JP); Tomoya FUJIMOTO, Nagoya-shi (JP)

(73) Assignee: FUJI CORPORATION, Chiryu (JP)

(21) Appl. No.: 19/160,686

(22) PCT Filed: Mar. 24, 2023
(86) PCT No.: PCT/JP2023/011822

§ 371 Date: Aug. 28, 2025

(51) Int. Cl. H05K 13/08

(52) U.S. Cl. CPC H05K 13/083; H05K 13/0815

(57) ABSTRACT

An electronic component mounting system includes an imaging section, a first component mounting state decision section, a second component mounting state decision section, a component change detection section, and a decision section automatic switching section. The imaging section images a component inspection region of a board. The first component mounting state decision section decides a mounting state of an electronic component based on an image captured by the imaging section by using a component mounting state decision device created by machine learning. The second component mounting state decision section decides the mounting state of the electronic component based on the image. The decision section automatic switching section switches from the first component mounting state decision section to the second component mounting state decision section when the component change detection section detects a change in the electronic component.

### TECHNICAL FIELD

A technique disclosed in the present description relates to an electronic component mounting system and an electronic component mounting inspection method.

### BACKGROUND ART

A line for mounting electronic components on a board generally includes a solder printing machine, a printing inspection machine, a component mounter, a reflow oven, a board visual inspector, and the like. With the component mounter, electronic components are mounted at mounting positions on a board. Immediately after the electronic component is mounted, the electronic component is imaged by a camera of the component mounter, and a visual inspection is performed to check whether the electronic component is present at the mounting position by image recognition based on the captured image. In recent years, machine learning has sometimes been used for such a visual inspection. As a conventional technique, for example, a technique disclosed in Patent Literature 1 (WO2019/155593) is known. In the technique disclosed in this publication, a component-specific trained model created by machine learning is used to determine whether an electronic component picked up by a suction nozzle is picked up normally or abnormally, and the electronic component decided to be picked up normally is mounted on a board. After the components are mounted, an inspection is performed to check whether a mounting failure has occurred, and a mounting failure occurrence rate is calculated for each component. Then, a threshold for deciding the mounting failure occurrence rate is set in advance, and it is decided whether there is an electronic component whose mounting failure occurrence rate exceeds the decision threshold. When there is an electronic component that exceeds the decision threshold, it is decided that the accuracy of image recognition for the electronic component is low, and additional training is started to adjust the component-specific trained model. In this case, additional training is performed based on an image obtained by actually capturing the electronic component.

### BRIEF SUMMARY

### Technical Problem

Incidentally, even electronic components that share the same product number may differ in appearance or surface design when the electronic components come from different vendors or lots. When such a change occurs in the electronic components, it can become difficult to stably perform the visual inspection based on the captured image. Therefore, in the conventional method, when an error occurs in a result of a component presence/absence inspection, a user needs to repeatedly perform additional training until the inspection is stabilized by temporarily stopping board production, which takes time and effort. In addition, in the conventional technique of Patent Literature 1, although the additional training can be automatically started, since a condition for starting the additional training is an increase in the mounting failure occurrence rate, the occurrence of the mounting failure cannot be prevented in advance.

Therefore, the present description provides a technique for stably performing a component presence/absence inspection during component mounting while maintaining board production efficiency.

### Solution to Problem

The present description provides an electronic component mounting system for mounting an electronic component on a board. The electronic component mounting system includes an imaging section, a first component mounting state decision section, a second component mounting state decision section, a component change detection section, and a decision section automatic switching section. The imaging section images a component inspection region of the board including the electronic component mounted on the board. The first component mounting state decision section decides a mounting state of the electronic component based on an image captured by the imaging section by using a component mounting state decision device created by machine learning. The second component mounting state decision section is provided separately from the first component mounting state decision section and decides the mounting state of the electronic component based on the image. The component change detection section detects whether a change has occurred in the electronic component to be mounted. When the component change detection section detects the change in the electronic component, the decision section automatic switching section performs automatic switching from the first component mounting state decision section to the second component mounting state decision section and causes the second component mounting state decision section to decide the mounting state of the electronic component. Therefore, with the above-described configuration, when there is no change in the electronic component to be mounted, the mounting state of the electronic component is decided using the component mounting state decision device created by machine learning. In addition, even when a change occurs in the electronic component to be mounted, the mounting state of the electronic component is decided without using the component mounting state decision device. This eliminates the need to stop board production, making it possible to stably perform a component presence/absence inspection during component mounting while maintaining board production efficiency.

In addition, the present description provides an electronic component mounting inspection method of inspecting a mounting state of an electronic component mounted on a board based on an image obtained by capturing a component inspection region including the electronic component. The electronic component mounting inspection method includes a first component mounting state decision step, a component change detection step, and a decision section automatic switching step. In the first component mounting state decision step, a mounting state of an electronic component is decided based on the image by using a component mounting state decision device created by machine learning. In the component change detection step, it is detected whether a change has occurred in the electronic component to be mounted. In the decision section automatic switching step, when the change in the electronic component is detected in the component change detection step, automatic switching from a first component mounting state decision section to a second component mounting state decision section provided separately from the first component mounting state decision section is performed. Further, in the decision section automatic switching step, the second component mounting state decision section decides the mounting state of the electronic component based on the image.

### BRIEF DESCRIPTION OF DRAWINGS

FIG. 1 is a schematic plan view illustrating an electronic component mounting system of an example.

FIG. 2 is a schematic cross-sectional view illustrating a component mounter.

FIG. 3 is a schematic view illustrating an electronic component mounting inspection method.

(a) of FIG. 4 is a schematic plan view illustrating a board before a component is mounted thereon, and (b) of FIG. 4 is a schematic plan view illustrating a first image.

(a) of FIG. 5 is a schematic plan view illustrating the board after a component is mounted thereon, and (b) of FIG. 5 is a schematic plan view illustrating a second image.

### DESCRIPTION OF EMBODIMENTS

(Aspect 1) In an electronic component mounting system provided in the present description, a second component mounting state decision section may be a component presence/absence decision section configured to decide whether an electronic component is present at a mounting position by performing difference processing of comparing an image of a component inspection region captured before the component is mounted with an image of the component inspection region captured after the component is mounted.

(Aspect 2) The electronic component mounting system according to Aspect 1 may further include an additional training section configured to collect, as training data, the image that is captured after the component is mounted and that is acquired during the difference processing performed by the second component mounting state decision section and use the training data in additional training for generating a new component mounting state decision device.

(Aspect 3) The electronic component mounting system according to Aspect 2 may further include a component mounter configured to mount the electronic component on a board, and a management computer configured to manage the component mounter, and the additional training section may be provided in the management computer.

(Aspect 4) In the electronic component mounting system according to Aspect 3, a first component mounting state decision section may be provided in the component mounter. When it is determined that the additional training section has completed the new component mounting state decision device, the management computer may transmit the new component mounting state decision device to the component mounter, and a decision section automatic switching section may replace the current component mounting state decision device with the new component mounting state decision device, and perform automatic switching from the second component mounting state decision section to the first component mounting state decision section to decide a mounting state of the electronic component.

(Aspect 5) In the electronic component mounting system according to Aspect 4, the management computer may perform a performance evaluation on the new component mounting state decision device, and determine that the new component mounting state decision device has been completed when an evaluation result that the new component mounting state decision device has performance equal to or higher than a predetermined level is obtained.

(Aspect 6) In the electronic component mounting system according to any one of Aspects 1 to 5, a component change detection section may detect whether a change has occurred in at least one component information item selected from a component name, a vendor name, and a lot of the electronic component, and the decision section automatic switching section may perform automatic switching from a first component mounting state decision section to the second component mounting state decision section when a decision result of the component change detection section is positive, and need not perform the automatic switching when the decision result of the component change detection section is negative.

(Aspect 7) In the electronic component mounting system according to any one of Aspects 1 to 5, a component change detection section may detect whether a change has occurred in at least one component information item selected from a component name, a vendor name, and a lot of the electronic component, and the decision section automatic switching section may perform automatic switching from a first component mounting state decision section to the second component mounting state decision section when a decision result of the component change detection section is positive, and perform the automatic switching in a case where a change occurs in a supply status of the electronic component and need not perform the automatic switching in a case where no change occurs in the supply status of the electronic component, when the decision result of the component change detection section is negative.

(Aspect 8) In the electronic component mounting system according to Aspect 7, the case where a change occurs in the supply status of the electronic component may refer to a case where splicing work is performed on a tape that supplies the electronic component.

### EXAMPLE

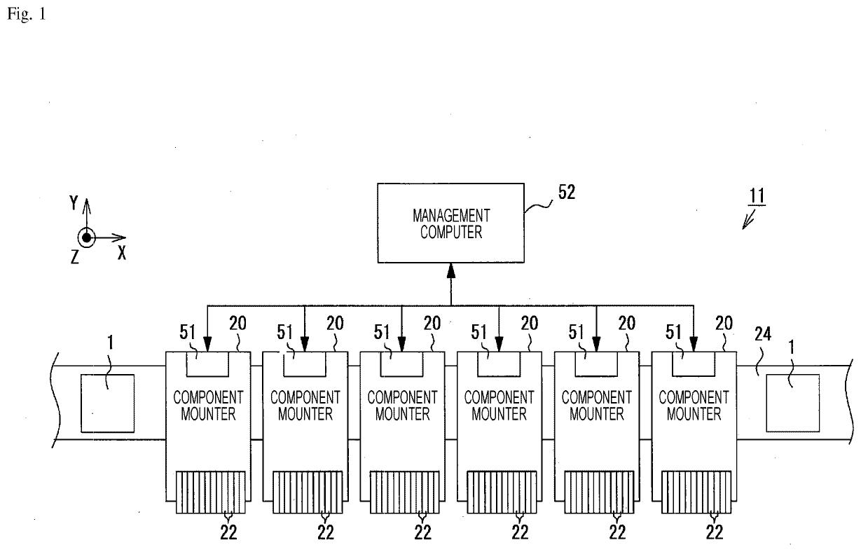

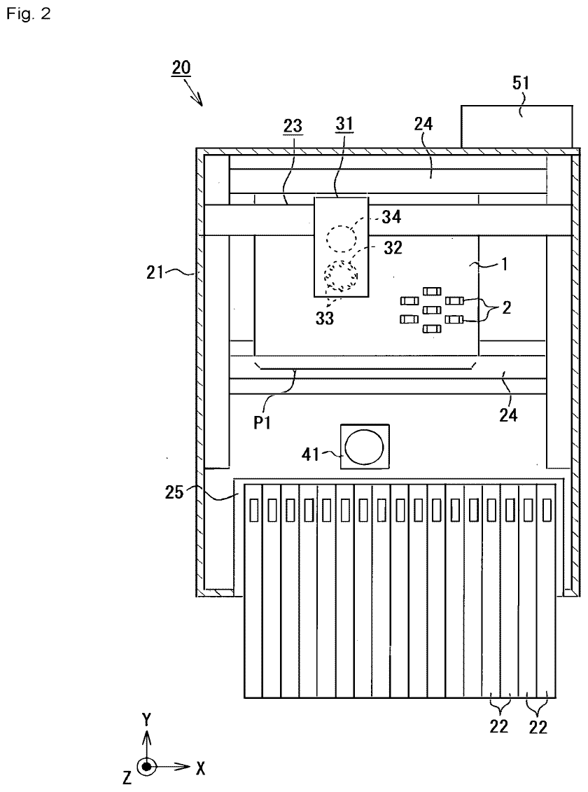

Hereinafter, electronic component mounting system 11 of the present example and an electronic component mounting inspection method performed by electronic component mounting system 11 will be described with reference to the drawings. FIG. 1 is a schematic plan view illustrating electronic component mounting system 11 of the present example. Electronic component mounting system 11 is a system for mounting electronic component 2 (see FIG. 2) on board 1. Electronic component mounting system 11 is configured by arranging multiple component mounters 20 along a conveyance direction (X direction) of board 1. Electronic component 2 is, for example, a component having component body 3 and multiple terminals 4 provided on component body 3, and specific examples thereof include semiconductor packages such as a quad flat package (QFP) and a ball grid array (BGA), and chip components such as chip resistors and chip capacitors.

A solder printing machine and a printing inspection machine (neither of which is illustrated) are disposed upstream of multiple component mounters 20. The solder printing machine prints a solder pattern on board 1 and carries out board 1 on which the solder pattern has been printed to the printing inspection machine. The printing inspection machine inspects the solder pattern printed on board 1 and carries out board 1 after the solder pattern inspection to component mounter 20. In addition, a reflow oven and a board visual inspector (neither of which is illustrated) are disposed downstream of multiple component mounters 20. The reflow oven performs a reflow process on board 1 carried out from component mounter 20. That is, the reflow oven heats board 1 that has been carried in to melt the solder, and solders electronic component 2 to board 1. The board visual inspector machine inspects board I after the component is mounted thereon, which is carried out from the reflow oven. Board visual inspector inspects whether electronic component 2 is normally mounted on board 1. When electronic component 2 is normally mounted on board 1, board visual inspector carries board 1 out of electronic component mounting system 11.

As illustrated in FIGS. 1 and 2, component mounter 20 is a device for mounting electronic component 2 on board 1. Component mounter 20 includes multiple component feeders 22, XY robot 23, board conveyance lane 24, head unit 31, part camera 41, control device 51, and the like.

Each of component feeders 22 accommodates multiple electronic components 2. Component feeder 22 is detachably attached to feeder holding section 25 and supplies electronic component 2 to head unit 31. Component feeder 22 of the present example is a tape type feeder that accommodates multiple electronic components 2 on a tape.

XY robot 23 moves head unit 31 between above component feeder 22 and above board 1 by moving head unit 31 in an X direction and a Y direction. XY robot 23 includes a guide rail that guides head unit 31, a moving mechanism that moves head unit 31 along the guide rail, a motor that drives the moving mechanism, and the like. XY robot 23 is housed inside housing 21 and is disposed above board 1. Head unit 31 is moved by XY robot 23 in a space from above component feeder 22 to above board 1.

Board conveyance lane 24 is a device that performs work of carrying board 1 into component mounter 20, work of positioning carried-in board 1 before the component is mounted thereon at work position PI, and work of carrying out board 1 after the component is mounted thereon from work position PI. Board conveyance lane 24 of the present example may include, for example, a pair of belt conveyors, a support device (not illustrated) that is attached to the belt conveyors and that supports board 1 from below, and a drive device (not illustrated) that drives the belt conveyors. Board 1 is conveyed from upstream (left side in FIG. 1) to downstream (right side in FIG. 1) of electronic component mounting system 11.

Head unit 31 is a movable unit that mounts electronic component 2 on board 1. Head unit 31 includes component mounting head 32 and mark camera 34 (an example of an imaging section). Component mounting head 32 is attached to a lower surface side of head unit 31 and includes multiple suction nozzles 33. Each of suction nozzles 33 is detachably supported by component mounting head 32. Each of suction nozzles 33 is configured to be lifted and lowered in a vertical direction (Z direction) by an actuator (not illustrated) accommodated in component mounting head 32 and to pick up electronic component 2.

In order to mount electronic component 2 on board 1 using head unit 31, first, suction nozzle 33 is moved downward until a pickup surface of suction nozzle 33 comes into contact with electronic component 2 accommodated in component feeder 22. Next, electronic component 2 is picked up by suction nozzle 33, and suction nozzle 33 is moved upward. When the process in which suction nozzle 33 picks up electronic component 2 is completed, XY robot 23 is driven to position head unit 31 with respect to board 1. Then, suction nozzle 33 is lowered toward board 1 to mount electronic component 2 on board 1. Head unit 31 and suction nozzle 33 are automatically exchanged by an exchange robot (not illustrated).

Mark camera 34 is mounted in the vicinity of component mounting head 32 in head unit 31, and is configured to be movable together with component mounting head 32. Mark camera 34 moves above board 1 carried to work position Pl by board conveyance lane 24, images a mark (not illustrated) attached to board 1, and images component inspection region Al (see (a) of FIG. 4 and (a) of FIG. 5) of board 1. Mark camera 34 is configured using, for example, an imaging element such as a charge coupled device (CCD) or a complementary metal oxide semiconductor (CMOS).

Part camera 41 is provided at a position between component feeder 22 and board conveyance lane 24 and below a movement path of head unit 31. Part camera 41 images electronic component 2 picked up by head unit 31 from below. Part camera 41 is also configured using, for example, an imaging element such as a CCD or a CMOS.

Control device 51 is formed of a computer including CPU, a memory, and the like. Control device 51 is communicably connected to component feeder 22, XY robot 23, board conveyance lane 24, head unit 31, part camera 41, and the exchange robot via a bus. Management computer 52 (see FIG. 1) that manages each component mounter 20 is communicably connected to control device 51 via a bus. Each control device 51 controls the operation of each part (component feeder 22, XY robot 23, board conveyance lane 24, head unit 31, part camera 41, and exchange robot) based on a production program stored in management computer 52. Through this control, each control device 51 executes a mounting process of mounting multiple electronic components 2 on board 1, and the like.

In addition, trained data (an example of a component mounting state decision device) is stored in the memory in control device 51. The memory also stores a component presence/absence decision program. The trained data is created as follows. First, two types of images are prepared: “multiple images before electronic component 2 is mounted (component-absent images)” and “multiple images in which electronic component 2 is normally mounted (component-present images)”. Next, features extracted from these images are trained to create trained data.

Next, an electronic component mounting inspection method will be described. First, control device 51 drives board conveyance lane 24 to carry board 1 to work position Pl in component mounter 20. Then, control device 51 drives XY robot 23 to move head unit 31 to a component pickup position, and causes suction nozzle 33 of head unit 31 to pick up electronic component 2 at the component pickup position. Thereafter, control device 51 moves head unit 31 to board 1 while passing head unit 31 above part camera 41, drives part camera 41 during the movement to image electronic component 2, and checks a state of electronic component 2.

Next, control device 51 inspects a mounting state of electronic component 2 based on an image obtained by capturing component inspection region Al (see (a) of FIG. 4 and (a) of FIG. 5) set on board 1. Specifically, first, control device 51 drives mark camera 34 to image a mark (not illustrated) attached to board 1, and executes image recognition processing based on imaging data thereof to recognize a position where electronic component 2 is to be mounted. Next, control device 51 drives mark camera 34 to image component inspection region Al (including the component mounting position) before the component is mounted, thereby obtaining first image 61 (see (b) of FIG. 4). When control device 51 decides the mounting state of electronic component 2 (whether electronic component 2 is present) using a component presence/absence decision device (trained data) created by machine learning, the step of acquiring first image 61 may be omitted. Next, control device 51 lowers suction nozzle 33 to release picked-up electronic component 2. By this operation, electronic component 2 is mounted on board 1.

Then, control device 51 drives mark camera 34 again to image component inspection region Al after a component is mounted, thereby obtaining second image 62 (see (b) of FIG. 5). In this case, control device 51 (an example of a first component mounting state decision section) decides the mounting state of electronic component 2 (whether electronic component 2 is present) based on the image by using a component presence/absence decision device (trained data) created by machine learning (first component mounting state decision step). Specifically, it is decided whether electronic component 2 is present at the mounting position by inputting a feature of second image 62, which is a decision target of the mounting state, to the trained data. As long as no change occurs in electronic component 2, the first component mounting state decision section continues the decision.

Incidentally, even electronic components 2 that share the same product number may differ in appearance or surface design when the electronic components come from different vendors or lots. When such a change occurs in electronic component 2, there is a possibility that the presence or absence of electronic component 2 cannot be accurately decided even based on images 61 and 62. Therefore, in the present example, for example, the following processing is performed.

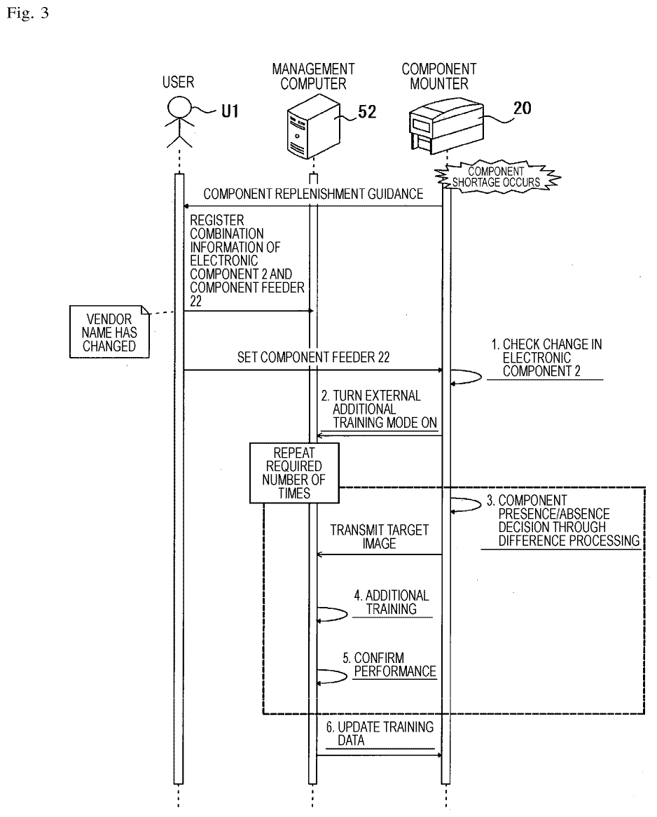

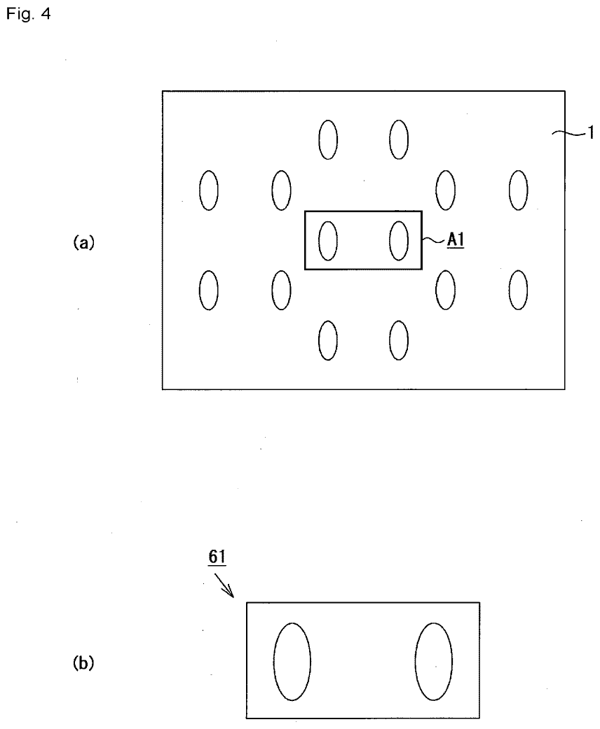

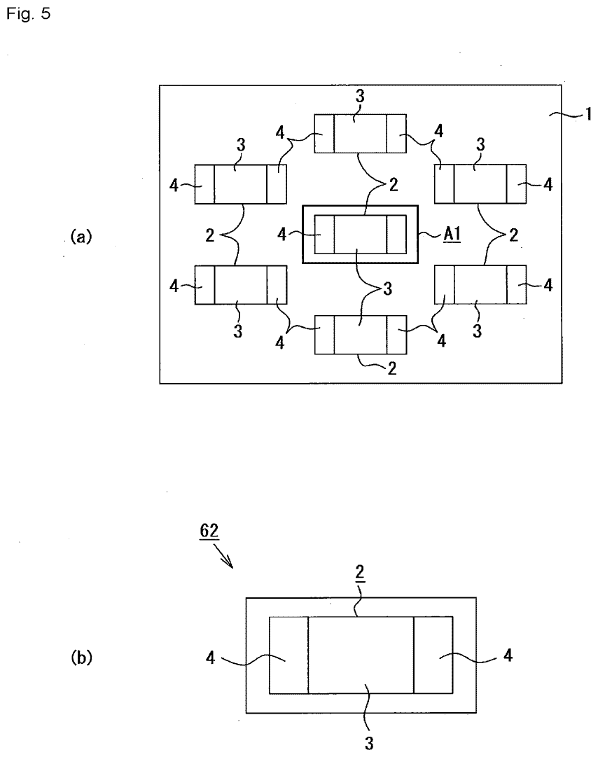

For example, as illustrated in FIG. 3, when a component shortage occurs in predetermined component mounter 20, control device 51 causes a display section (not illustrated) of component mounter 20 to display guidance (component replenishment guidance) for requesting replenishment of electronic component 2. Next, user U1 removes component feeder 22 in which the component shortage has occurred from feeder holding section 25 of component mounter 20, and prepares new component feeder 22. Further, user Ul registers combination information of electronic component 2 and component feeder 22 in prepared component feeder 22 in management computer 52. In addition, user Ul also registers component information of electronic component 2 (specifically, a component name, a vendor name, and a lot of electronic component 2) in management computer 52. Then, user UI attaches (sets) prepared component feeder 22 to feeder holding section 25. Alternatively, when a component shortage occurs in predetermined component mounter 20, user Ul may replenish electronic component 2 by performing splicing work. In this case, user Ul registers, in management computer 52, combination information of component feeder 22 on which the splicing work has been performed and electronic component 2 to be newly spliced. By registering the combination information of component feeder 22 and electronic component 2 in management computer 52 during the splicing work, it is possible to determine that a change has occurred in a supply status of electronic component 2. The combination information of component feeder 22 and electronic component 2 may be registered in control device 51. In this case, control device 51 can determine, based on the registered information, that a change has occurred in the supply status of electronic component 2.

In the subsequent component change detection step, control device 51 (an example of a component change detection section) detects whether a change has occurred in electronic component 2 to be mounted (see “1.” in FIG. 3). Specifically, control device 51 communicates with management computer 52 to acquire the component information registered in management computer 52, thereby comparing the component information “before” the component shortage with the component information “after” the component shortage, and detects whether a change has occurred in the component information. In addition, control device 51 detects whether a change has occurred in at least one component information item selected from a component name, a vendor name, and a lot of electronic component 2. In FIG. 3, since the vendor name of electronic component 2 has changed, control device 51 decides that electronic component 2 has been switched.

In the subsequent decision section automatic switching step, control device 51 (an example of a decision section automatic switching section) automatically switches the function of the first component mounting state decision section of control device 51 to the function of the second component mounting state decision section of control device 51 when the change in electronic component 2 is detected in the component change detection step, that is, when a decision result of the component change detection section is positive. The second component mounting state decision section is provided in control device 51 functionally separately from the first component mounting state decision section. In addition, when the decision result of the component change detection section is negative, control device 51 performs automatic switching from the first component mounting state decision section to the second component mounting state decision section even in a case where a change occurs in the supply status of electronic component 2. The case where a change occurs in the supply status of electronic component 2 refers to a case where splicing work of splicing another tape accommodating new electronic component 2 onto the tape of component feeder 22 that supplies electronic component 2 is performed. When the decision result of the component change detection section is negative, control device 51 does not perform the automatic switching in a case where no change occurs in the supply status of electronic component 2. In addition, when the automatic switching is performed, control device 51 instructs management computer 52 to change to the “external additional training mode” (see “2.” in FIG. 3).

When the mode is changed to the “external additional training mode”, control device 51 cannot inspect the mounting state of electronic component 2 using trained data. In this case, control device 51 (an example of a second component mounting state decision section) decides the mounting state of electronic component 2 based on images 61 and 62. Control device 51 of the present example decides whether electronic component 2 is present at the mounting position by performing difference processing of comparing an image (first image 61) of component inspection region A1 captured before the component is mounted with an image (second image 62) of component inspection region A1 captured after the component is mounted (see “3.” in FIG. 3). The image (second image 62) that is captured after the component is mounted and that is acquired during the difference processing is transmitted to management computer 52 (target image transmission).

Specifically, first, control device 51 creates a difference image of component inspection region A1 using images 61 and 62. Next, control device 51 performs binarization processing after smoothing the difference image with a smoothing filter. Further, control device 51 calculates an area of a difference region of the difference image (a portion of component inspection region A1 that has changed between before and after the component is mounted). Then, control device 51 calculates a difference between the area of the difference region and an area of electronic component 2, and, when the calculated difference is a minute value, control device 51 uses the difference image as the “component-present” image and decides that electronic component 2 is present at the mounting position. Specifically, when entire electronic component 2 appears in the image (second image 62) of component inspection region A1 after the component is mounted (in a case of normal mounting), the area of the difference region of the difference image is, for example, 180000 μm². In this case, a difference between the area of the difference region and the area of electronic component 2 (for example, 180000 μm²) is 0 μm² and is decided to be a minute value. The “minute value” may be designated by user U1 or may be a fixed value.

To the contrary, when the difference between the area of the difference region and the area of electronic component 2 is not a minute value, control device 51 does not use the difference image as the “component-present” image and decides that electronic component 2 is not present at the mounting position. Specifically, when electronic component 2 does not appear in the image (second image 62) after the component is mounted (when a mounting error has occurred in electronic component 2), there is no change in the image, so that the area of the difference region of the difference image is 0 μm². In this case, the difference between the area of the difference region and the area of electronic component 2 (for example, 180000 μm²) is 180000 μm² and it is decided that the difference is not a minute value. When at least a part of electronic component 2 appearing in the image (second image 62) after the component is mounted protrudes from second image 62 (when a mounting deviation has occurred in electronic component 2), the area of the difference region of the difference image is, for example, 60000 μm². In this case, the difference between the area of the difference region and the area of electronic component 2 (for example, 180000 μm²) is 120000 μm² and it is also decided that the difference is not a minute value. The decision of whether electronic component 2 is present at the mounting position is repeatedly performed for the required number of times.

In addition, management computer 52 (an example of an additional training section) collects, as training data, second image 62 that is transmitted from control device 51 and that is acquired during the difference processing, and uses the collected training data in additional training for generating new training data (see “4.” in FIG. 3). Specifically, management computer 52 extracts features for machine learning from collected second image 62, performs additional training, and generates new trained data.

Next, management computer 52 performs a performance evaluation on the generated new trained data, and determines that the new trained data has been completed when an evaluation result that the new trained data has performance equal to or higher than a predetermined level is obtained (see “5.” in FIG. 3). Specifically, management computer 52 performs a test on an image sample group using the new trained data, and measures a correct answer rate of a component presence/absence inspection (decision of whether electronic component 2 is present at the mounting position). In addition, management computer 52 decides whether new trained data has been completed based on the correct answer rate of the component presence/absence inspection, and decides whether to end the “external additional training mode”. The decision of whether the new trained data has been completed (the decision of whether to end the “external additional training mode”) is performed based on the “correct answer rate for only images 61 and 62 after the component shortage” and “the number of samples of images 61 and 62 after the component shortage”. For example, when the number of samples is 1000 or more and the correct answer rate is 99.9% or more, management computer 52 determines that the new trained data has been completed and decides to end the “external additional training mode”. This method uses the “correct answer rate for electronic component 2 currently being used” as an indicator for decision, so that, if the production has been halted for a while, the number of samples is insufficient, and the decision has to start from sample zero. Therefore, in the present example, it is decided whether the correct answer rate satisfies a pass condition after a certain number or more of samples are collected. The pass condition may be freely set by user U1.

Further, when it is determined that the new trained data has been completed by the additional training section, management computer 52 transmits the new trained data to component mounter 20. Then, control device 51 (an example of a decision section automatic switching section) of component mounter 20 replaces the current trained data with the new trained data (see “6.” in FIG. 3). With this, the function of the second component mounting state decision section of control device 51 is automatically switched to the function of the first component mounting state decision section of control device 51. Thereafter, control device 51 decides the mounting state of electronic component 2 through machine learning instead of deciding the mounting state of electronic component 2 through the difference processing (component presence/absence inspection). That is, the component mounting state decision function of control device 51 is restored to its original state.

As described above, in electronic component mounting system 11 of the present example, control device 51 detects whether a change has occurred in electronic component 2 to be mounted. When a change occurs in electronic component 2 to be mounted, control device 51 decides the mounting state of electronic component 2 based on first image 61 and second image 62 without using the component mounting state decision device created by machine learning (component presence/absence inspection). Accordingly, the component presence/absence inspection can be performed even when a change occurs in electronic component 2, eliminating the need to stop the board production. That is, it is possible to stably perform the component presence/absence inspection during component mounting while maintaining board production efficiency.

In electronic component mounting system 11 of the present example, additional training for generating new trained data is performed not by control device 51 of component mounter 20 but by management computer 52 outside component mounter 20. Accordingly, additional training can be performed without imposing a burden on control device 51.

In electronic component mounting system 11 of the present example, when a change in electronic component 2 is detected, control device 51 decides the mounting state of electronic component 2 through the difference processing (component presence/absence inspection). However, the component presence/absence inspection through the difference processing has a problem in that it takes more time than the component presence/absence inspection through machine learning, because it is necessary to capture not only the image (second image 62) after the component is mounted but also the image (first image 61) before the component is mounted.

Therefore, in the present example, as soon as new trained data is generated by management computer 52, the current trained data is replaced with the new trained data, and control device 51 starts the component presence/absence inspection through machine learning. As a result, the time lost for the component presence/absence inspection can be minimized, thereby minimizing takt-time reduction.

Although one example has been described above, the specific aspect is not limited to the example described above. In the above example, the additional training section of management computer 52 outside component mounter 20 performs additional training; however, the configuration is not limited to this. For example, in another example, an additional training section may be provided in control device 51 in component mounter 20 to perform additional training.

In the above example, when control device 51 of component mounter 20 detects that a change has occurred in the component information (component name, vendor name, and lot) of electronic component 2, management computer 52 performs additional training for generating new trained data; however, the configuration is not limited to this. For example, in another example, when control device 51 detects a change in the component information of electronic component 2 and detects a change in the supply status of electronic component 2 due to the splicing work, management computer 52 may perform additional training.

In the above example, even if the component information of electronic component 2 does not change, management computer 52 performs additional training as long as control device 51 detects a change in the supply status of the electronic component 2 due to the splicing work being performed; however, the configuration is not limited to this. For example, in another example, even if control device 51 detects a change in the supply status of electronic component 2 due to the splicing work being performed, when no change in the component information of the electronic component 2 is detected, management computer 52 need not perform additional training.

In the above example, the component presence/absence decision is performed as the decision of the mounting state of electronic component 2; however, the configuration is not limited to this. For example, in another example, the component position decision may be performed as the decision of the mounting state of electronic component 2.

In the above example, the second component mounting state decision section decides whether electronic component 2 is present at the mounting position by performing the difference processing; however, the configuration is not limited to this. For example, in another example, a decision device that performs processing other than the difference processing may be used to decide whether electronic component 2 is present at the mounting position.

Although a specific example of the present disclosure has been described in detail above, this is merely illustrative and does not limit the scope of the claims. The technique described in the claims includes various modifications and changes to the specific example described above. The technical elements described in the present description or the drawings exhibit technical usefulness alone or in various combinations and are not limited to the combinations described in the claims as filed. In addition, the techniques illustrated in the present description or the drawings can simultaneously achieve multiple objects and provide technical usefulness by achieving one object itself in multiple objects.

### LIST OF REFERENCE SIGNS

1: Board
2: Electronic component
11: Electronic component mounting system
20: Component mounter
34: Mark camera as imaging section
51: Control device as first component mounting state decision section, second component mounting state decision section, component change detection section, decision section automatic switching section, and component presence/absence decision section
52: Management computer as additional training section
61: First image as image
62: Second image as image
A1: Component inspection region

1. An electronic component mounting system for mounting an electronic component on a board, the electronic component mounting system comprising:
an imaging section configured to image a component inspection region of the board including the electronic component mounted on the board;
a first component mounting state decision section configured to decide a mounting state of the electronic component based on an image captured by the imaging section by using a component mounting state decision device created by machine learning;
a second component mounting state decision section provided separately from the first component mounting state decision section and configured to decide the mounting state of the electronic component based on the image;
a component change detection section configured to detect whether a change has occurred in the electronic component to be mounted; and
a decision section automatic switching section configured to, when the component change detection section detects the change in the electronic component, perform automatic switching from the first component mounting state decision section to the second component mounting state decision section and cause the second component mounting state decision section to decide the mounting state of the electronic component.

2. The electronic component mounting system according to Claim 1, wherein the second component mounting state decision section is a component presence/absence decision section configured to decide whether the electronic component is present at a mounting position by performing difference processing of comparing an image of the component inspection region captured before the component is mounted with an image of the component inspection region captured after the component is mounted.

3. The electronic component mounting system according to Claim 2, further comprising:
an additional training section configured to collect, as training data, the image that is captured after the component is mounted and that is acquired during the difference processing performed by the second component mounting state decision section and use the training data in additional training for generating a new component mounting state decision device.

4. The electronic component mounting system according to Claim 3, further comprising:
a component mounter configured to mount the electronic component on the board; and
a management computer configured to manage the component mounter,
wherein the additional training section is provided in the management computer.

5. The electronic component mounting system according to Claim 4,
wherein the first component mounting state decision section is provided in the component mounter,
when it is determined that the additional training section has completed the new component mounting state decision device, the management computer transmits the new component mounting state decision device to the component mounter, and
the decision section automatic switching section replaces the current component mounting state decision device with the new component mounting state decision device, and performs automatic switching from the second component mounting state decision section to the first component mounting state decision section to decide the mounting state of the electronic component.

6. The electronic component mounting system according to Claim 5, wherein the management computer performs a performance evaluation on the new component mounting state decision device, and determines that the new component mounting state decision device has been completed when an evaluation result that the new component mounting state decision device has performance equal to or higher than a predetermined level is obtained.

7. The electronic component mounting system according to claim 1,
wherein the component change detection section detects whether a change has occurred in at least one component information item selected from a component name, a vendor name, and a lot of the electronic component, and
the decision section automatic switching section
performs automatic switching from the first component mounting state decision section to the second component mounting state decision section when a decision result of the component change detection section is positive, and
does not perform the automatic switching when the decision result of the component change detection section is negative.

8. The electronic component mounting system according to claim 1,
wherein the component change detection section detects whether a change has occurred in at least one component information item selected from a component name, a vendor name, and a lot of the electronic component, and
the decision section automatic switching section
performs automatic switching from the first component mounting state decision section to the second component mounting state decision section when a decision result of the component change detection section is positive, and
performs the automatic switching in a case where a change occurs in a supply status of the electronic component and does not perform the automatic switching in a case where no change occurs in the supply status of the electronic component, when the decision result of the component change detection section is negative.

9. The electronic component mounting system according to Claim 8, wherein the case where a change occurs in the supply status of the electronic component refers to a case where splicing work is performed on a tape that supplies the electronic component.

10. An electronic component mounting inspection method of inspecting a mounting state of an electronic component mounted on a board based on an image obtained by capturing a component inspection region including the electronic component, the electronic component mounting inspection method comprising:
a first component mounting state decision step of deciding the mounting state of the electronic component based on the image by using a component mounting state decision device created by machine learning;
a component change detection step of detecting whether a change has occurred in the electronic component to be mounted; and
a decision section automatic switching step of, when the change in the electronic component is detected in the component change detection step, performing automatic switching from a first component mounting state decision section to a second component mounting state decision section provided separately from the first component mounting state decision section and causing the second component mounting state decision section to decide the mounting state of the electronic component based on the image.
